(19) United States
(12) Patent Application Publication
(10) Pub. No.: US 2012/0244273 A1
(43) Pub. Date: Sep. 27, 2012

(54) SYSTEM AND A METHOD FOR SOLDER MASK INSPECTION

(75) Inventors: Avi Levy, Mitzpe Aviv (IL); Roni Flieswasser, Grimbergen (BE); Albert Yafe, Raanana (IL); Michael Lev, Yokneam (IL)

(73) Assignee: CAMTEK LTD., Migdal Haemek (IL)

(21) Appl. No.: 13/391,834

(22) PCT Filed: Jul. 6, 2010
(86) PCT No.: PCT/IL10/00539

§ 371 Date: Jun. 11, 2012

Related U.S. Application Data
(60) Provisional application No. 61/223,074, filed on Jul. 6, 2009.

(51) Int. Cl. H05K 3/22

(52) U.S. Cl. 427/8; 118/712

(57) ABSTRACT

A system and a method for method for printing a solder mask on a printed circuit board (PCB), the method includes: acquiring images of multiple areas of a PCB by an inspection unit while the PCB is supported by a mechanical stage; determining spatial differences between a model of the PCB and the PCB based on the images; determining solder mask ink deposition locations based on (i) the spatial differences, and (ii) locations of the model of the PCB that should be coated with the solder mask ink; and printing solder mask ink on the solder mask deposition locations by a printing unit, while the PCB is supported by the mechanical stage.

### RELATED APPLICATIONS

This application claims priority of U.S. provisional patent application Ser. No. 61/223,074, filing date 6 Jul. 2009, which is incorporated herein by reference.

### BACKGROUND OF THE INVENTION

One or more Printed Circuit Boards (PCBs) may be included in a single panel. Prior art PCB production systems have dedicated Automatic Optical Inspection (AOI) systems that are separated from printing systems. The prior art PCB manufacturing process may include: (i) inspection of a PCB by an AOI system (ii) PCB cleaning and surface preparation; (iii) solder mask coating by a dedicated printing machine (which can either be done by silk screen printing (photo image able or not), Curtin coating or spray coating (photo image able)), (iv) Tack free curing; (v) UV exposure; (vi) solder mask development; (vii) solder mask inspection (by a dedicated system); and (viii) final curing.

This process requires many panel handling form various different systems such as the AOIs, cleaning equipment, solder mask deposition equipment etc., thus increasing significantly handling related defects which reduce the production line yield.

### SUMMARY OF THE INVENTION

A method may be provided. According to an embodiment of the invention the method may include: acquiring images of multiple areas of a PCB by an inspection unit while the PCB is supported by a mechanical stage; determining spatial differences between a model of the PCB and the PCB based on the images; determining solder mask ink deposition locations based on (i) the spatial differences, and (ii) locations of the model of the PCB that should be coated with the solder mask ink; and printing solder mask ink on the solder mask deposition locations by a printing unit, while the PCB is supported by the mechanical stage.

The method may include determining whether the PCB is of at least a desired quality, based on at least some of the images; and printing solder mask ink only if the PCB is of at least the desired quality.

The method may include inspecting the PCB after a completion of the printing of the solder mask ink to detect missing solder mask ink locations that should have been coated by solder mask ink but are not coated by solder mask ink, while the PCB is supported by the mechanical stage; and printing solder mask ink on at the missing solder mask ink locations while the PCB is supported by the mechanical stage.

The method may include inspecting the actual PCB after depositing solder mask ink at a plurality of solder mask ink deposition locations to detect missing solder mask ink locations that should have been coated by solder mask ink but are not coated by solder mask ink, while the PCB is supported by the mechanical stage; and printing solder mask ink on at, the missing solder mask ink locations while the PCB is supported by the mechanical stage.

The method may include inspecting the PCB after depositing solder mask ink at a plurality of solder mask deposition locations to detect excess solder mask ink; and removing the excess solder mask ink by a repair unit.

The method may include inspecting the PCB after depositing solder mask ink at a plurality of solder mask deposition locations to detect contaminations in the solder mask area and removing the contaminations by a repair unit while. The removal may be executed while the PCB is supported by a mechanical stage.

The method may include: acquiring images of multiple areas of the PCB by an inspection unit while introducing movement between the inspection unit and a bridge that is located above the mechanical stage; and printing solder mask ink on the solder mask deposition locations by the printing unit while introducing movement between the printing unit and the bridge.

The method may include: acquiring images of multiple areas of the PCB by an inspection unit while introducing movement between the inspection unit and a first bridge that is located above the mechanical stage; and printing solder mask ink on the solder mask deposition locations by the printing unit while introducing movement between the printing unit a second bridge.

The method may include: acquiring images of multiple areas of the PCB by an inspection unit while moving the mechanical stage along a first direction and moving the inspection unit along a second direction; and printing solder mask ink on the solder mask deposition locations while moving the mechanical stage along a first direction and moving the printing unit along a second direction.

The method may include curing the solder mask ink by the printing unit.

The determining of the spatial differences may include performing global alignment and local alignment.

A system for solder mask printing on a printed circuit board (PCB) is provided. According to an embodiment of the invention the system may include: a mechanical stage for supporting the PCB; an inspection unit for acquiring images of multiple areas of a PCB while the PCB is supported by the mechanical stage;

a processor for determining spatial differences between a model of the PCB and the PCB based on the images and for determining solder mask ink deposition locations based on (i) the spatial differences, and (ii) locations of the model of the PCB that should be coated with the solder mask ink; and a printing unit for printing solder mask ink on the solder mask deposition locations, while the PCB is supported by the mechanical stage.

The processor may be configured to determine whether the PCB is of at least a desired quality, based on at least some of the images and wherein the printing unit may be arranged to print solder mask ink only if the PCB is of at least the desired quality.

The inspection unit may be arranged to inspect the PCB after a completion of the printing of the solder mask ink to detect missing solder mask ink locations that should have been coated by solder mask ink but are not coated by solder mask ink, while the PCB is supported by the mechanical stage; and wherein the printing unit may be arranged to print solder mask ink on at the missing solder mask ink locations while the PCB is supported by the mechanical stage.

The inspection unit may be arranged to inspect the actual PCB after depositing solder mask ink at a plurality of solder mask ink deposition locations to detect missing solder mask ink locations that should have been coated by solder mask ink but are not coated by solder mask ink, while the PCB is supported by the mechanical stage; and wherein the printing unit may be arranged to print solder mask ink on at the missing solder mask ink locations while the PCB is supported by the mechanical stage.

The inspection unit may be arranged to inspect the PCB after a after depositing solder mask ink at a plurality of solder mask deposition locations to detect excess solder mask ink; and wherein the system further comprises a repair unit for removing the excess solder mask ink while the PCB is supported by the mechanical stage.

The model of the PCB may be a computer aided design model of the PCB.

The inspection unit may be arranged to acquire images of multiple areas of the PCB by an inspection unit while introducing movement between the inspection unit and a bridge that is located above the mechanical stage; and wherein the printing unit may be arranged to print solder mask ink on the solder mask deposition locations by the printing unit while introducing movement between the printing unit and the bridge.

The inspection unit may be arranged to acquire images of multiple areas of the PCB by an inspection unit while introducing movement between the inspection unit and a first bridge that is located above the mechanical stage; and wherein the printing unit may be arranged to print solder mask ink on the solder mask deposition locations by the printing unit while introducing movement between the printing unit a second bridge.

The inspection unit may be arranged to acquire images of multiple areas of the PCB by an inspection unit while moving the mechanical stage along a first direction and moving the inspection unit along a second direction; and wherein the printing unit may be arranged to printing solder mask ink on the solder mask deposition locations while moving the mechanical stage along a first direction and moving the printing unit along a second direction.

The printing unit may be arranged to cure the solder mask ink by the printing unit.

The processor may be arranged to determine the spatial differences comprising performing global alignment and local alignment.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

FIGS. 1 and 5 illustrate a system according to various embodiments of the invention;

FIGS. 2, 3, 4 and 7 illustrates portions of a system according to various embodiments of the invention; and

FIG. 6 is a flow chart of a method according to an embodiment of the invention.

### DETAILED DESCRIPTION OF THE DRAWINGS

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the following detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The systems and methods herein disclosed include a digital printing of the solder mask ink—wherein the solder mask ink is applied only where it is required on the PCB. This facilitates an inspection of the solder mask printing quality immediately after the solder mask ink deposition process.

According to an embodiment of the invention, the system includes a sensor such as but not limited to a line sensor (other sensors such as area sensors can be used) for capturing the panel and solder mask ink location. With the herein disclosed systems and methods, the panel is inspected either prior to the printing phase for panel approval before solder mask ink deposition or right after the printing process at a stage where the panel can still be fixed.

According to an embodiment of the invention, the system is capable of inspecting the PCB prior to the solder mask deposition, to verify that there are no defects in its outer layers, print the solder mask on the PCB, and inspect the solder mask deposition to verify good coverage and accurate deposition.

Conveniently, various stages of the printing process can be executed by the same system, while the PCB is supported by the same mechanical stage. This may allow a provision of a printing process and system that is characterized by in line and real time (or almost real time) feedback, a faster cycle time, a reduction of reducing handling related defect, a reduction in yield losses, and reduction in printing process time and cost.

According to an embodiment of the invention, a system is disclosed, that is conveniently a solder mask direct digital material deposition system, which enables a digital deposition of the required “coating” on PCBs in order to protect the metallic wiring on the surface which is not the metallic pads.

According to an embodiment of the invention, Computer Aided Design (CAD) data may be used, e.g. for adjusting the drop deposition location according to the grabbed panel image. Thus, the disclosed systems and methods may facilitate high accuracy, production flexibility and environmental friendly and cleanly process without wasting problematic chemicals.

According to an embodiment of the invention, currently available golden board data may be used, e.g. for adjusting the drop deposition location according to the grabbed panel image. Thus, the disclosed systems and methods may facilitate high accuracy, production flexibility and environmental friendly and cleanly process without wasting problematic chemicals.

According to an aspect of the invention, disclosed systems and methods include combined printing of solder mask and inspecting the printed product (not necessarily the solder mask).

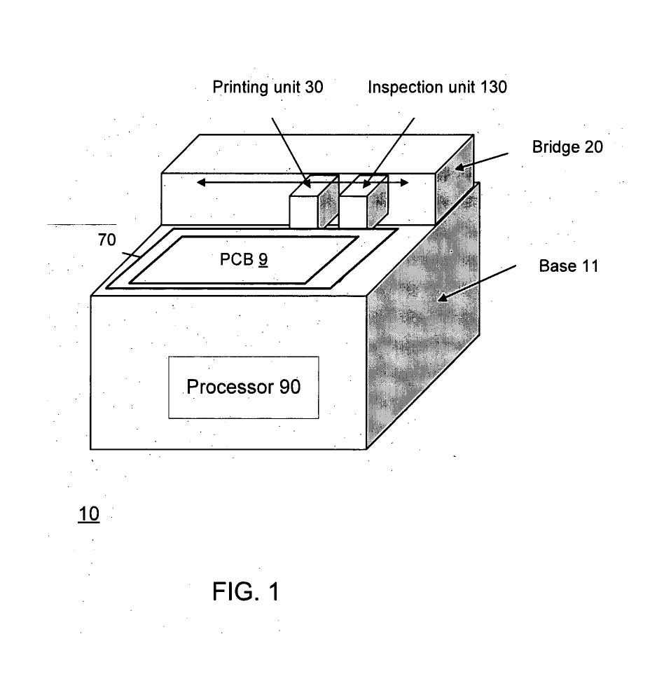

FIG. 1 illustrates a system 10, according to an embodiment of the invention.

System 10 includes a base 11 that may include mechanical and electrical components.

FIG. 1 illustrates system 10 as including bridge 20, inspection unit 130, printing unit 30 and an object handling sub-system 70.

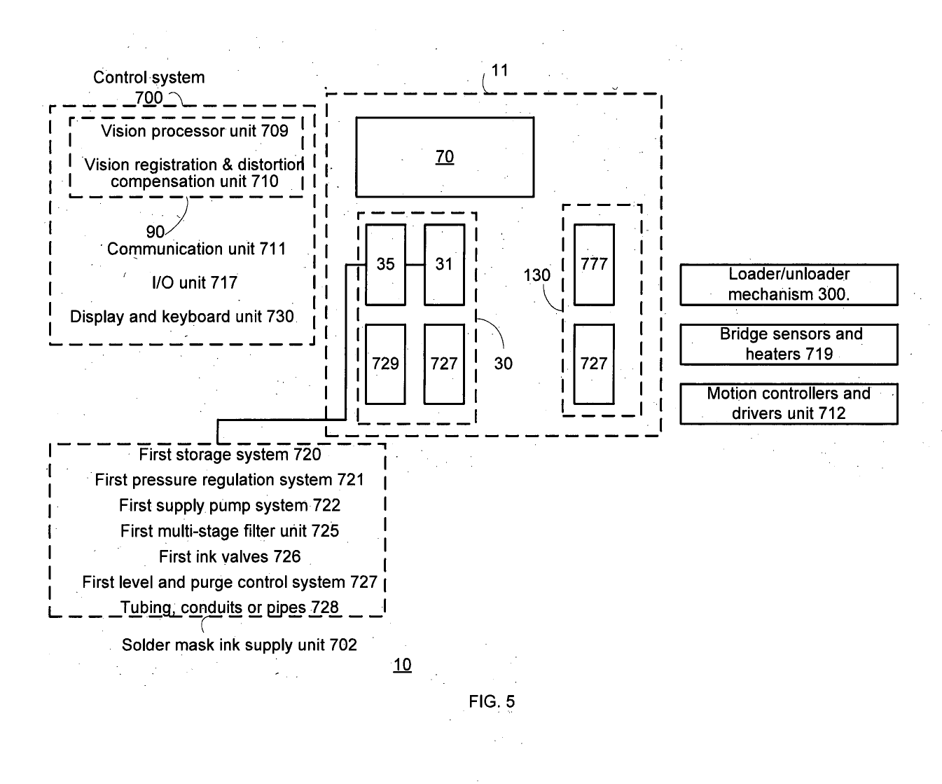

The object handling sub-system 70 support a PCB 9 (or a multiple PCB panel). An example of various components included in base 11 is provided in FIG. 5.

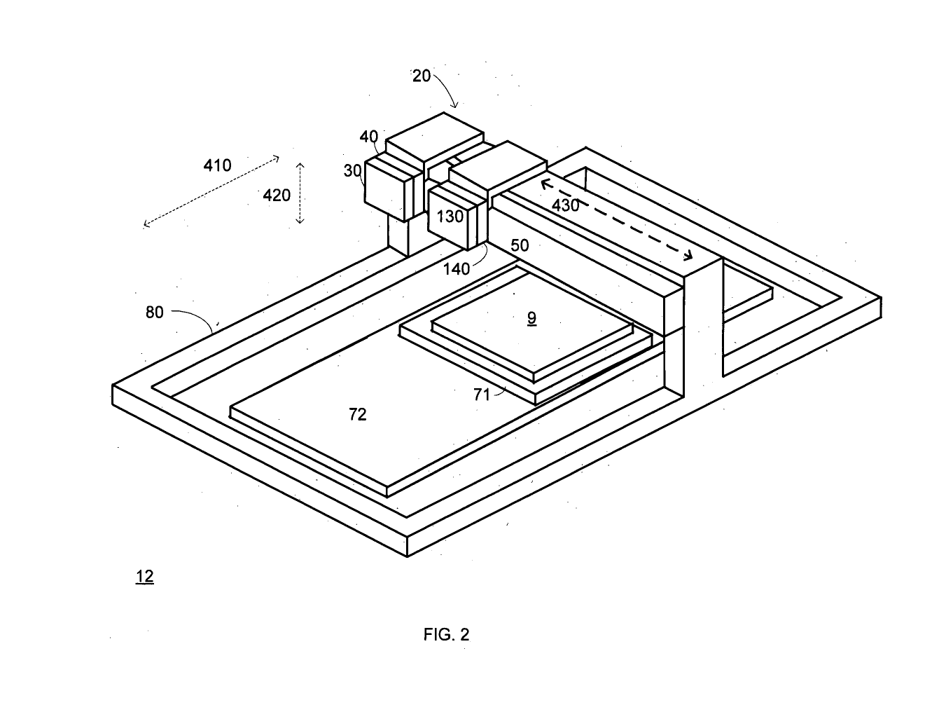

FIG. 2 illustrates a first portion 200 of system 10 according to an embodiment of the invention.

First portion 200 includes bridge 20, frame 80, printing unit 30, inspection unit 130, first motor 40, bridge motor 50, second motor 140 and PCB handling sub-system 70.

The multiple motors facilitates movements along various directions. For simplicity of explanation various structural elements connected to the motors or in touch with the motors (such as rails, chains and the like) are not shown.

PCB handling sub-system (also referred to as mechanical stage) 70 includes an object supporter 71 that supports the PCB 9 and may firmly hold it after the PCB 9 is being aligned and positioned in a desired location and orientation. PCB handling sub-system 70 also includes a motorized system 72 that may move object supporter 71 (and PCB 9) along first direction 410 (for example—x-axis).

First motor 40 moves printing unit 30 along second direction 420 (for example—z-axis). Second motor 140 moves inspection unit 130 along the second direction 420. Bridge motor 50 moves printing unit 30 and, additionally or alternatively inspection unit 130 along a longitudinal axis 430 (for example—y-axis) of the bridge 20. A PCB 9 is placed on object supporter 71. It is noted that motorized system 72 can be held by (or be supported by) a part (not shown) of frame 80.

FIG. 2 illustrates first direction 410, second direction 420 and longitudinal axis 430 as being perpendicular to each other. It is noted that these directions (and axis) may be oriented to each other by less than (or more than) 90 degrees.

Bridge 20 is fixed to frame 80 and rigid. Frame 80 is located in a horizontal plane and has a rectangular shape. It is noted that frame 80 may have other shapes and may be oriented in relation to the horizon.

Bridge 20 provides a highly accurate and stable structure the does not move during the printed process and during the inspection process, and simplifies the control scheme of the imaging printing process. The fixed and rigid bridge 20 does not include extensive moving parts and its maintenance is simple and cheap. Bridge 20 includes a horizontal structural element (that defines its longitudinal axis 430) and two vertical structural elements that define a space in which PCB 9 may move.

Bridge 20 is configured to accommodate in a precise manner printing unit 30. Printing unit 30 may include jet nozzles for injecting a solder mask ink to form a solder mask on the surface of an object.

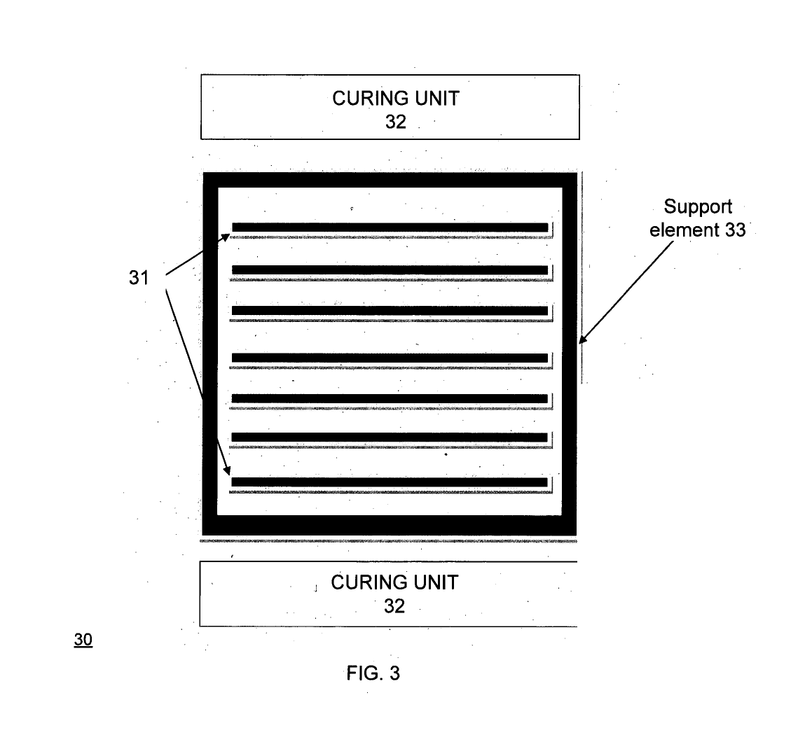

The jet nozzles of the printing unit 30 may be arranged in various manners. For example, jet nozzles (denoted 31 in FIG. 3) may be arranged in lines that are parallel to each other and are spaced apart from each other to form an array of jet nozzles.

FIG. 3 also illustrates (i) supporting elements 33 that are connected between the jet nozzles 31 and the first motor 40 and (ii) a pair of curing units 32 that are located at both sides of the array of jet nozzles 31. These curing units 32 can use UV radiation, heat or any other radiation based curing techniques. The number of curing units 32 and their position may differ from those illustrated in FIG. 3. For example, one of more curing units can be separated from the printing unit and can, for example, be coupled to the bridge 20.

The array may have a rectangular shape as illustrated in FIG. 3, a diamond like shape, a rectangular shape, a circular shape and the like.

The printing unit 30 and the inspection unit 130 may be controlled independently from each other. Both units may be activated in parallel to each other. For example—if the object that is being processed is a multiple—PCB panel then the printing unit 30 can print solder mask patterns on one PCB of the panel while the inspection unit can image another PCB of the panel. The same applies to different areas of a PCB that is large enough to be included simultaneously in the field of view of both heads 30 and 130.

It is noted that the inspection head 130 and the printing head 30 may be located on opposing sides of the bridge 20 (one in front of bridge 20—as illustrated in FIG. 2 and the other unit at the rear side of the bridge 20)—each unit is connected to a different bridge motor. Yet for another example—the printing unit 30 and the inspection unit 130 may be positioned at different heights.

It is noted that the mentioned above inspection unit 130 may include illumination optics, one or more light sources, collection optics and one or more sensors such as a line sensor, an area sensor and the like.

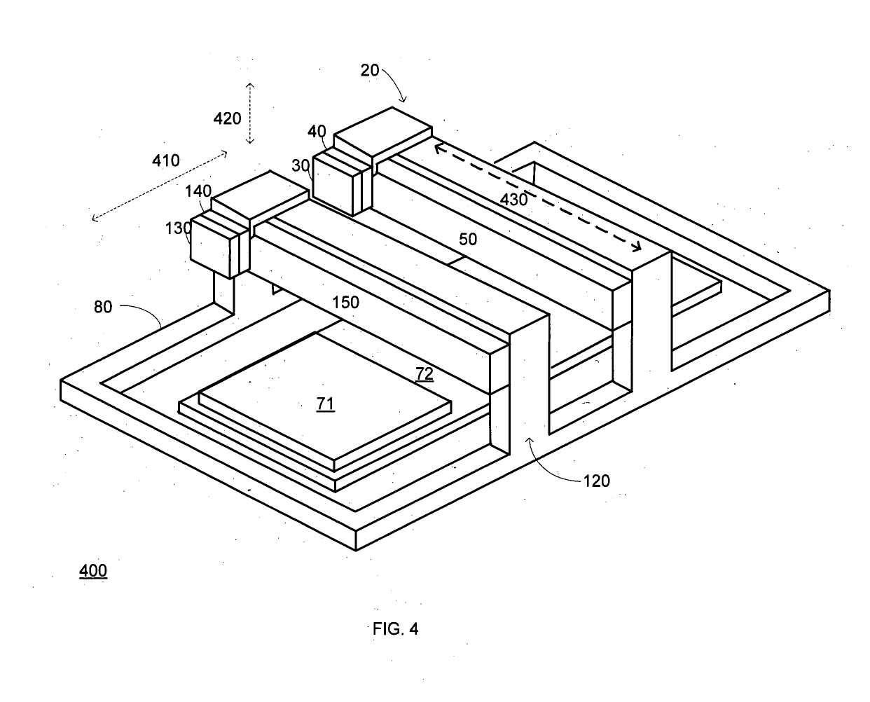

FIG. 4 illustrates a first portion 400 of system 10 according to an embodiment of the invention.

First portion 400 of FIG. 4 differs from first portion 200 of FIG. 2 by including two bridges (20 and 120) instead of a single bridge (20). The printing unit 30 is coupled (via motors 40 and 50 and/or additional structural elements such as rails) to the first bridge 20 while the inspection unit 130 is coupled (via motors 140 and 150 and/or additional structural elements such as rails) to the second bridge 120.

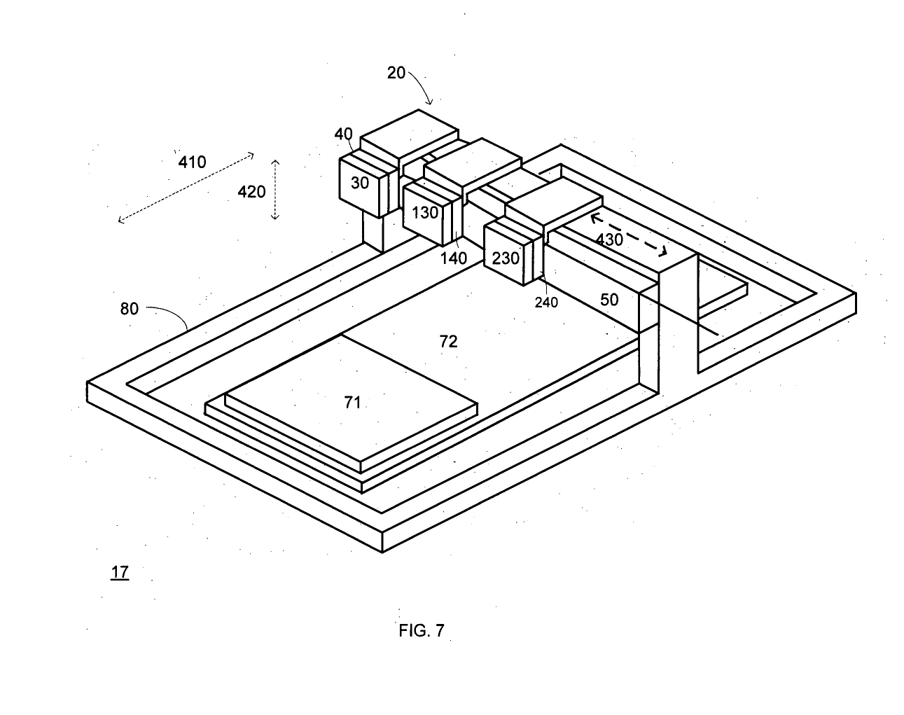

According to an embodiment of the invention a curing unit (not shown) can be included in the printing unit 30, coupled to one bridge (As illustrate din FIG. 7) or be located between bridges 20 and 120.

FIG. 4 illustrates two bridges 20 and 120 that are parallel to each other but this is not necessarily so.

FIG. 5 illustrates system 10 according to another embodiment of the invention.

System 10 include control system 700, motion controllers 712, vision registration and distortion compensation unit 710, PCB handling sub-system 70, bridge sensors and heaters 719, illumination unit 777 (that may belong to inspection unit 130), imaging optics and sensor 778 (that belong to inspection unit 130), curing unit 729, curing control 727 that controls the curing process, jet nozzle drivers 715, jet nozzles 31, and solder mask ink supply unit 702.

It is noted that system 10 may include any first portion out of first portions 200 and 400.

Control system 700 can include one or more controllers, processor, micro-controllers, and the like. It may include a man machine interface for receiving commands, providing status, displaying images of objects and the like.

Control system 700 may be configured to perform at least one of the following operations:

A. Convert solder mask ink pattern information to commands that activate jet nozzles, wherein the solder mask pattern information is indicative of solder mask ink deposition locations that are determined based on the spatial differences, and locations of the model of the PCB that should be coated with the solder mask ink.

B. Perform image processing of images obtained before, during and/or after the printing process.

C. Receive image and status information during the printing process.

D. Manage malfunctions by activating backup jet nozzles, changing the timing of ink jet operations (amend firing times of jet nozzles).

E. Control the movement motors such as motors 40, 50, 140 and 150, object handling sub-system 70, and

F. Control a provision of jettable substrates to the jet nozzles 31.

Control system 700 may include one or more card cages to accommodate various electronic cards and provide supply voltages and data paths to and from these cards. It may include an image processing system that may include software modules, hardware modules or a combination thereof. It may convert commonly supported image file formats such as PDL (Page Description Language), postscript or other vector-type of graphic files into a pixel-mapped page image, which is in effect the actual print data that is transferred to the printer to print a pattern, representing the image of the data file. A widely used file format is e.g. the Gerber or extended Gerber format. Converted print data may be provided via a data path and synchronizing board of control system and be transferred to jet print head drivers 705. This converted print data may be provided from the drivers to the multiple jet nozzles, situated on the static and rigid printing bridge 20 (or bridges 20 and 120). The Synchronizing board 704 provides the means of synchronizing the data timing with the vacuum table 708 movement.

Optionally, control system 700 includes a vision system, including a processor 90 that may include vision processor unit 709 and vision registration & distortion compensation unit 710, which is employed for various tasks, in particular for solder mask printing, further below described in more detail.

Optionally, control system 700 includes a communication unit 711 for providing data into motion controller and drivers unit 712, which transforms the electrical positional signals, representative of the positional data, into electric control signals, commonly pulses that operate the object handling sub-system 70, first print jet head motor 40 and second print jet motor 50. Object handling sub-system 70 may include a motor and a vacuum table denoted 708 in FIG. 8.

Optionally, system 700 includes one or more additional motors (not shown) that may change the vertical distance between vacuum table 700 and printing bridge 20. These additional motors may also be controlled by vertical positional control signals from motion controller and drivers unit 712. This vertical movement may assist in compensating for thickness differences between different objects.

I/O unit 717 of control system 700 communicates with the various components of system 10, such as inter alia, bridge sensors & heaters & system heaters 719 and loader/unloader 720.

I/O unit 717 may also communicate with various components of the system such as valves (not shown) that control the vacuum level at different locations of vacuum table. This allows a reduction of the vacuum level in areas that are proximate to jettable substance that was jetted on the object and was not cured. These valves may achieve area addressable suction force in vacuum table 708, as illustrated in U.S. Pat. No. 6,754,551 of Zohar which is incorporated herein by reference. These values form a part of area-addressable suction force valve system 718 that provides different vacuum levels to different parts of vacuum table 708.

The jet nozzles 31 may receive the first jettable substance from solder mask ink supply unit 702.

The solder mask ink supply unit 702 may include: (i) a first storage system 720 that may include one or more containers, including a main container and a secondary container that functions as a level controlling system by applying gravity and physic's principal of communicating vessels, thus controlling the negative meniscus pressure; (ii) a first pressure regulation system 721, utilizing above-mentioned principal of communicating vessels; (iii) a first supply pump system 722, controlled by control system 700, (iv) a first multi-stage filter unit 725, controlling maximum particle size of ink substance, (v) multiple first ink valves 726; (vi) a first level and purge control system 727 with a multitude of level sensing devices; (vii) a first wiping, solvent washing, purging and priming unit (not shown); (viii) a first fluid collection vessel, collecting ink and cleaning fluids (not shown); (ix) a first air bubbles drainage system (not shown); (x) a first temperature control system (not shown), that may include a first heating unit, a first temperature sensing unit and a first temperature control unit, (xi) tubing, conduits or pipes 728 for supplying the first jettable substance to first jet print head 30.

Subsequent initial curing (making the dispensed image substantially tack-free), or optionally, complete curing, is achieved in curing unit 32, wherein accordingly to the utilized ink type, either thermal, IR (infra-red) oven or curing by UV (ultra-violet) exposure is applied.

Various operator related interactions with the system are performed utilizing a display and keyboard unit 730 of control system 700.

FIG. 7 illustrates a first portion 700 of system 10 according to an embodiment of the invention.

First portion 700 differs from first portion 200 by having a repair unit 230 that is connected to a removal unit motor 240 that introduce z-axis movement in relation to the bridge 20. Repair unit 230 may remove excess solder mask by laser or mechanical means.

According to another embodiment of the invention the repair unit 230 is separated from system 10 and may apply, for example, chemical etching processes on the PCB. Alternatively, the removal process may not be executed while the PCB is supported by the mechanical stage but by a repair unit that belongs to the system. Yet alternatively, multiple repair units may be provided including chemical based removal units, mechanical based removal units and radiation based removal units.

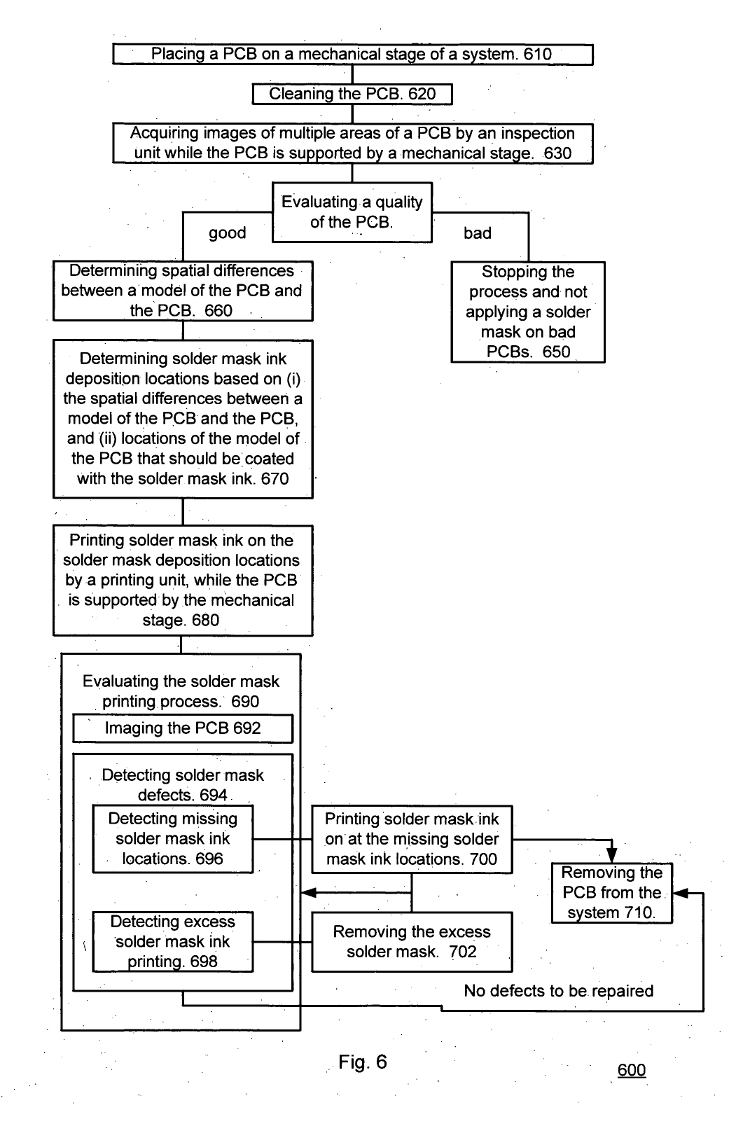

FIG. 6 illustrates a method 600 according to an embodiment of the invention.

Method 600 starts by stage 610 of placing a PCB on a mechanical stage of a system. This stage may be referred to as loading the PCB to the system. The PCB may be included in a panel that includes multiple PCB and in this case the entire panel is loaded to the system and the different PCBs of the panel can be processed by the following stages of method 600.

Stage 610 may include holding the PCB to a vacuum and clamp table or otherwise firmly holding the PCB so that prevent unwanted movements of the PCB during the execution of method 600.

Stage 610 is followed by stage 620 of cleaning the PCB.

Stage 620 is followed by stage 630 of acquiring images of multiple areas of a PCB by an inspection unit while the PCB is supported by a mechanical stage. These areas may overlap, may partially overlap, may be spaced apart from each other, my cover the entire PCB or only one or more portions thereof. Each area can be imaged once or multiple times.

Stage 630 is followed by stage 640 of evaluating a quality of the PCB. The quality of the PCB may reflect whether the PCB is functional (“good”) or defective (“bad”). It is noted that more than two classes of PCBs can be provided (as well as more than a pair of corresponding quality levels). For example, some PCBs can be of problematic quality but their defects can be re-worked while the defects of other PCBs cannot be fixed (or are too costly to fix). For simplicity of explanation the following description refers to two classes of PCBs—good one and bad ones.

If, for example, stage 640 is applied to a panel that includes multiple PCB's then the quality of the panel can be calculated in response to the quality levels (defect levels) of these different PCB's. The quality level of the panel can be determined by applying one or more functions that take into account the quality of the different PCBs. For example—if one PCB is defective then the panel can be further processed but this single PCB may not undergo additional processes such as solder mask printing. Yet according to an embodiment of the invention a predefined number of defective PCBs can cause the entire panel to be regarded as a defective one.

Stage 640 may include applying a defect detection algorithm on the images (or some of the images) obtained during stage 630. Stage 640 may include comparing the images of the areas of the PCB to design data of the PCB, comparing the images to a reference PCB (such as a golden reference), and the like.

If the PCB is classified as a bad PCB—stage 640 is followed by stage 650 of stopping the process and not applying a solder mask on bad PCBs. Stage 650 can include repairing the PCB (or panel) or throwing it away.

If the PCB is classified as a good PCB then stage 640 is followed by stage 660 of determining spatial differences between a model of the PCB and the PCB.

Stage 660 may be based, at least in part, on images acquired during stage 630 and, additionally or alternatively, on images that may be obtained during stage 660.

Stage 660 may include performing global alignment and local alignment. Global alignment may include determining the overall deviations of the PCB from the model of the PCB, for example by calculating deviations of targets located near the edges of the PCB from their expected (deviation free) locations. Local alignment may include determining local deviations of portions of the PCB from their expected location. The deviations may results from deformation of the PCB during the manufacturing process and may include rotational deviations, shrink, stretches, and the like.

The spatial differences may be determines by locating alignment targets, measuring deviations in the locations of the alignment targets and calculating the spatial deviations of other portions of the PCB based on the measured deviations. Linear and, additionally or alternatively, non-linear functions may be used to provide the spatial deviation of the various portions of the PCB.

Stage 660 is followed by stage 670 of determining solder mask ink deposition locations based on (i) the spatial differences between a model of the PCB and the PCB, and (ii) locations of the model of the PCB that should be coated with the solder mask ink. The location of the model can form a desired image that includes desired target pixels—desired pixels that should be to be coated with solder mask ink.

The solder mask ink locations are adjusted to fit the PCB that is going to be covered with solder mask ink.

For example, the spatial differences can be represented by shift function (F(x,y)) or an array of spatial shift vectors that indicate the evaluated (or measured) shift of different portions of the PCB. This array or function is used to transform the desired target pixels (Pdesired_target(x,y)) to actual target pixels (Pactual_target(x,y)). Pactual_target(x,y)=F[Pdesired_target(x,y)]. The actual target pixels are also referred to as solder mask deposition locations.

Stage 670 may include adjusting computer aided design data of about the solder mask to compensate for spatial instability of the PCB.

Stage 670 is followed by stage 680 of printing solder mask ink on the solder mask deposition locations by a printing unit, while the PCB is supported by the mechanical stage. Stage 680 may include printing solder mask ink by jet nozzles and curing the solder mask ink by a curing unit. After the curing the solder mask ink can be dry or semi-dry.

Stage 680 is followed by stage 690 of evaluating the solder mask printing process. Stage 690 may includes stage 692 of imaging the PCB and stage 694 of detecting solder mask defects.

Stage 694 may include stage 696 of detecting missing solder mask ink locations—location of the PCB that should have been coated by solder mask ink but are not coated by solder mask ink.

Stage 696 may be followed by stage 700 of printing solder mask ink on at the missing solder mask ink locations. Stage 700 may be followed by stage 690 or be followed by stage 710 of removing the PCB from the system—unloading the PCB from the mechanical stage that supported the PCB during stages 620-690.

Additionally or alternatively, stage 694 may include stage 698 of detecting excess solder mask ink printing—locations that were not supposed to be coated by solder mask ink but were actually coated by solder mask ink. Stage 698 may be followed by stage 702 of removing the excess solder mask. Stage 702 may be followed by stage 690 or be followed by stage 710 of removing the PCB from the system—unloading the PCB from the mechanical stage that supported the PCB during stages 620-690.

Stage 690 may include comparing the solder mask (or solder mask pattern) that was actually printed to the solder mask ink deposition locations determined during stage 670.

Method 600 can be executed by any of the systems illustrated above. For example, stage 630 can include acquiring images of multiple areas of the PCB by an inspection unit while introducing movement between the inspection unit and a bridge that is located above the mechanical stage. The same can be applied during stage 690. Stage 680 may include printing solder mask ink on the solder mask deposition locations by the printing unit while introducing movement between the printing unit and the bridge.

Yet for another example, stage 630 may include acquiring images of multiple areas of the PCB by an inspection unit while introducing movement between the inspection unit and a first bridge that is located above the mechanical stage. The same movement can be introduced during stage 690. Stage 680 may include printing solder mask ink on the solder mask deposition locations by the printing unit while introducing movement between the printing unit a second bridge.

Yet for a further example, stage 630 may include acquiring images of multiple areas of the PCB by an inspection unit while moving the mechanical stage along a first direction and moving the inspection unit along a second direction. Stage 680 can include printing solder mask ink on the solder mask deposition locations while moving the mechanical stage along a first direction and moving the printing unit along a second direction.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A method for printing a solder mask on a printed circuit board (PCB), the method comprises:
acquiring images of multiple areas of a PCB by an inspection unit while the PCB is supported by a mechanical stage;
determining spatial differences between a model of the PCB and the PCB based on the images;
determining solder mask ink deposition locations based on (i) the spatial differences, and (ii) locations of the model of the PCB that should be coated with the solder mask ink; and
printing solder mask ink on the solder mask deposition locations by a printing unit, while the PCB is supported by the mechanical stage.

2. The method according to claim 1, further comprising:
determining whether the PCB is of at least a desired quality, based on at least some of the images; and
printing solder mask ink only if the PCB is of at least the desired quality.

3. The method according to claim 1, comprising:
inspecting the PCB after a completion of the printing of the solder mask ink to detect missing solder mask ink locations that should have been coated by solder mask ink but are not coated by solder mask ink, while the PCB is supported by the mechanical stage; and
printing solder mask ink on at the missing solder mask ink locations while the PCB is supported by the mechanical stage.

4. The method according to claim 1, comprising: inspecting the actual PCB after depositing solder mask ink at a plurality of solder mask ink deposition locations to detect missing solder mask ink locations that should have been coated by solder mask ink but are not coated by solder mask ink, while the PCB is supported by the mechanical stage; and printing solder mask ink on at the missing solder mask ink locations while the PCB is supported by the mechanical stage

5. The method according to claim 1, comprising:
inspecting the PCB after a after depositing solder mask ink at a plurality of solder mask deposition locations to detect excess solder mask ink; and
removing the excess solder mask ink by a repair unit.

6. The method according to claim 1, wherein the models of the PCB is a computer aided design models of the PCB.

7. The method according to claim 1, comprising:
acquiring images of multiple areas of the PCB by an inspection unit while introducing movement between the inspection unit and a bridge that is located above the mechanical stage; and
printing solder mask ink on the solder mask deposition locations by the printing unit while introducing movement between the printing unit and the bridge.

8. The method according to claim 1, comprising:
acquiring images of multiple areas of the PCB by an inspection unit while introducing movement between the inspection unit and a first bridge that is located above the mechanical stage; and
printing solder mask ink on the solder mask deposition locations by the printing unit while introducing movement between the printing unit and a second bridge.

9. The method according to claim 1, comprising:
acquiring images of multiple areas of the PCB by an inspection unit while moving the mechanical stage along a first direction and moving the inspection unit along a second direction; and
printing solder mask ink on the solder mask deposition locations while moving the mechanical stage along a first direction and moving the printing unit along a second direction.

10. The method according to claim 1 comprising curing the solder mask ink by the printing unit.

11. The method according to claim 1 wherein the determining of the spatial differences comprising performing global alignment and local alignment.

12. A system for solder mask printing on a printed circuit board (PCB), the system comprises:
a mechanical stage for supporting the PCB;
an inspection unit for acquiring images of multiple areas of a PCB while the PCB is supported by the mechanical stage;
a processor for determining spatial differences between a model of the PCB and the PCB based on the images and for determining solder mask ink deposition locations based on (i) the spatial differences, and (ii) locations of the model of the PCB that should be coated with the solder mask ink; and
a printing unit for printing solder mask ink on the solder mask deposition locations, while the PCB is supported by the mechanical stage.

13. The system according to claim 12, wherein the processor is configured to determine whether the PCB is of at least a desired quality, based on at least some of the images and wherein the printing unit is arranged to print solder mask ink only if the PCB is of at least the desired quality.

14. The system according to claim 12, wherein the inspection unit is arranged to inspect the PCB after a completion of the printing of the solder mask ink to detect missing solder mask ink locations that should have been coated by solder mask ink but are not coated by solder mask ink, while the PCB is supported by the mechanical stage; and wherein the printing unit is arranged to print solder mask ink on at the missing solder mask ink locations while the PCB is supported by the mechanical stage.

15. The system according to claim 12, wherein the inspection unit is arranged to inspect the actual PCB after depositing solder mask ink at a plurality of solder mask ink deposition locations to detect missing solder mask ink locations that should have been coated by solder mask ink but are not coated by solder mask ink, while the PCB is supported by the mechanical stage; and wherein the printing unit is arranged to print solder mask ink on at the missing solder mask ink locations while the PCB is supported by the mechanical stage.

16. The system according to claim 12, wherein the inspection unit is arranged to inspect the PCB after a after depositing solder mask ink at a plurality of solder mask deposition locations to detect excess solder mask ink; and wherein the system further comprises a repair unit for removing the excess solder mask ink.

17. The system according to claim 12, wherein the model of the PCB is a computer aided design model of the PCB.

18. The system according to claim 12, wherein the inspection unit is arranged to acquire images of multiple areas of the PCB by an inspection unit while introducing movement between the inspection unit and a bridge that is located above the mechanical stage; and wherein the printing unit is arranged to print solder mask ink on the solder mask deposition locations by the printing unit while introducing movement between the printing unit and the bridge.

19. The system according to claim 12, wherein the inspection unit is arranged to acquire images of multiple areas of the PCB by an inspection unit while introducing movement between the inspection unit and a first bridge that is located above the mechanical stage; and wherein the printing unit is arranged to print solder mask ink on the solder mask deposition locations by the printing unit while introducing movement between the printing unit a second bridge.

20. The system according to claim 12, wherein the inspection unit is arranged to acquire images of multiple areas of the PCB by an inspection unit while moving the mechanical stage along a first direction and moving the inspection unit along a second direction; and wherein the printing unit is arranged to printing solder mask ink on the solder mask deposition locations while moving the mechanical stage along a first direction and moving the printing unit along a second direction.

21. The system according to claim 12 wherein the printing unit is arranged to cure the solder mask ink by the printing unit.

22. The system according to claim 12 wherein the processor is arranged to determine the spatial differences comprising performing global alignment and local alignment.
